(19) United States
(12) Patent Application Publication
(10) Pub. No.: US 2024/0079325 A1
(43) Pub. Date: Mar. 7, 2024

(54) HYBRID BACKSIDE DIELECTRIC FOR CLOCK AND POWER WIRES

(71) Applicant: International Business Machines Corporation, Armonk, NY (US)

(72) Inventors: Nicholas Anthony Lanzillo, Wynantskill, NY (US); Ruilong Xie, Niskayuna, NY (US); Huai Huang, Clifton Park, NY (US); Hosadurga Shobha, Shobha, NY (US); Lawrence A. Clevenger, Saratoga Springs, NY (US)

(21) Appl. No.: 17/823,971

(22) Filed: Sep. 1, 2022

(51) Int. Cl. H01L 23/528; H01L 21/768

(52) U.S. Cl. CPC H01L 23/5286; H01L 21/76802; H01L 21/76835

(57) ABSTRACT

Embodiments of the present invention are directed to processing methods and resulting structures having hybrid backside dielectrics. In a non-limiting embodiment of the invention, a front end of line structure is formed and a back end of line structure is formed on a first surface of the front end of line structure. A backside power delivery network is formed on a second surface of the front end of line structure opposite the first surface. The backside power delivery network includes a first set of interconnect lines in a first metallization level, a second set of interconnect lines in the first metallization level, and a hybrid backside dielectric structure. The hybrid backside dielectric structure includes a first dielectric material and a second dielectric material. The first set of interconnect lines are embedded in the first dielectric material and the second set of interconnect lines are embedded in the second dielectric material.

### BACKGROUND

The present invention generally relates to fabrication methods and resulting structures for semiconductor devices, and more specifically, to processing methods and resulting structures for providing a hybrid backside dielectric for clock and power wires.

The development of an integrated circuit (i.e., chip) involves several stages from design through fabrication. Many aspects of the development are performed iteratively to ensure that the chip ultimately manufactured meets all design requirements. Defining the chip architecture is one of the earliest phases of integrated circuit development. The power (e.g., power requirement), performance (e.g., timing), and area (i.e., space needed) for the resulting chip, collectively PPA, is one of the primary metrics by which integrated circuits are evaluated. PPA is largely a consequence of the chip architecture.

Semiconductor fabrication continues to evolve towards improving one or more aspects of PPA. For example, a higher number of active devices (mainly transistors) of ever decreasing device dimensions are placed on a given surface of semiconductor material. Density scaling has put a strain on the design and fabrication of the interconnects between the front end of line of the integrated circuit, consisting mainly of the active devices, and the contact terminals of the integrated circuit. In many chip architectures, all of these interconnects are incorporated in the back end of line (BEOL) structure of the integrated circuit, which includes a stack of metallization layers and vertical via connections built on top of the front end of line (FEOL) structure.

A key component of the BEOL structure is the power delivery network (PDN). The PDN of an integrated circuit is defined by the conductors and vias connected to the power supply (VDD) and ground (VSS) terminals of the chip. The PDN is responsible for delivering power to the individual devices in the front end. The integration of the PDN in the BEOL has become particularly challenging as device densities continue to scale. Backside power delivery is one known solution to this problem, and involves moving some (or most, or all) layers of the PDN from the front side of the integrated circuit to the back side. In a backside-style architecture, the repositioned layers are not formed on top of the FEOL, but are instead formed on the opposite side of the chip (i.e., on the backside of the semiconductor substrate onto which the active devices have been built).

### SUMMARY

Embodiments of the invention are directed to a method for forming a semiconductor device having a hybrid backside dielectric. A non-limiting example of the method includes forming a front end of line structure and forming a back end of line structure on a first surface of the front end of line structure. A backside power delivery network is formed on a second surface of the front end of line structure opposite the first surface. The backside power delivery network includes a first set of interconnect lines in a first metallization level, a second set of interconnect lines in the first metallization level, and a hybrid backside dielectric structure. The hybrid backside dielectric structure includes a first dielectric material and a second dielectric material. The first set of interconnect lines are embedded in the first dielectric material and the second set of interconnect lines are embedded in the second dielectric material. Advantageously, a hybrid backside dielectric increases control over the capacitance of each respective interconnect line.

In some embodiments, the first set of interconnect lines are electrically connected directly to each device region of the front end of line structure, while the second set of interconnect lines are not electrically connected to at least one device region of the front end of line structure. In some embodiments, the first set of interconnect lines include power supply (VDD) and ground (VSS) terminals and the second set of interconnect lines include a clock signal wire. Advantageously, configuring a hybrid backside dielectric in this manner increases VDD/VSS decoupling capacitance, reducing power supply noise, while also maintaining a low clock (or data) capacitance, reducing clock skew and/or signal delay.

In some embodiments, the first dielectric material includes a first dielectric constant and the second dielectric material includes a second dielectric constant less than the first dielectric constant. For example, in some embodiments, the first dielectric material includes a high-k dielectric and the first dielectric constant is greater than 3.7, while the second dielectric material includes a low-k dielectric and the second dielectric constant is less than 3.7. Advantageously, the first set of interconnect lines can be VDD/VSS lines embedded in the high-k dielectric to ensure high capacitance (minimizing decoupling capacitance), while the second set of interconnect lines can be clock signals embedded in the low-k dielectric to provide a low capacitance (minimizing clock skew and signal delay).

Embodiments of the invention are directed to a semiconductor structure. A non-limiting example of the semiconductor structure includes a front end of line structure and a back end of line structure on a first surface of the front end of line structure. A backside power delivery network is positioned on a second surface of the front end of line structure opposite the first surface. The backside power delivery network includes a first set of interconnect lines in a first metallization level, a second set of interconnect lines in the first metallization level, and a hybrid backside dielectric structure. The hybrid backside dielectric structure includes a first dielectric material and a second dielectric material. The first set of interconnect lines are embedded in the first dielectric material and the second set of interconnect lines are embedded in the second dielectric material.

Additional technical features and benefits are realized through the techniques of the present invention. Embodiments and aspects of the invention are described in detail herein and are considered a part of the claimed subject matter. For a better understanding, refer to the detailed description and to the drawings.

### BRIEF DESCRIPTION OF THE DRAWINGS

The specifics of the exclusive rights described herein are particularly pointed out and distinctly claimed in the claims at the conclusion of the specification. The foregoing and other features and advantages of the embodiments of the invention are apparent from the following detailed description taken in conjunction with the accompanying drawings in which:

FIG. 1A depicts a cross-sectional view taken along the line X1 (across gate in channel region) in FIG. 1E of a semiconductor wafer after an initial set of processing operations according to one or more embodiments of the invention;

FIG. 1B depicts a cross-sectional view taken along the line X2 (across gate in clock/signal region) in FIG. 1E of the semiconductor wafer after the initial set of processing operations according to one or more embodiments of the invention;

FIG. 1C depicts a cross-sectional view taken along the line Y1 (along gate in channel region) in FIG. 1E of the semiconductor wafer after the initial set of processing operations according to one or more embodiments of the invention;

FIG. 1D depicts a cross-sectional view taken along the line Y2 (across source/drain regions) in FIG. 1E of the semiconductor wafer after the initial set of processing operations according to one or more embodiments of the invention;

FIG. 1E depicts a top-down view of the semiconductor wafer after the initial set of processing operations according to one or more embodiments of the invention;

FIG. 2A depicts the cross-sectional view taken along the line X1 after a processing operation according to one or more embodiments of the invention;

FIG. 2B depicts the cross-sectional view taken along the line X2 after a processing operation according to one or more embodiments of the invention;

FIG. 2C depicts the cross-sectional view taken along the line Y1 after a processing operation according to one or more embodiments of the invention;

FIG. 2D depicts the cross-sectional view taken along the line Y2 after a processing operation according to one or more embodiments of the invention;

FIG. 3A depicts the cross-sectional view taken along the line X1 after a processing operation according to one or more embodiments of the invention;

FIG. 3B depicts the cross-sectional view taken along the line X2 after a processing operation according to one or more embodiments of the invention;

FIG. 3C depicts the cross-sectional view taken along the line Y1 after a processing operation according to one or more embodiments of the invention;

FIG. 3D depicts the cross-sectional view taken along the line Y2 after a processing operation according to one or more embodiments of the invention;

FIG. 4A depicts the cross-sectional view taken along the line X1 after a processing operation according to one or more embodiments of the invention;

FIG. 4B depicts the cross-sectional view taken along the line X2 after a processing operation according to one or more embodiments of the invention;

FIG. 4C depicts the cross-sectional view taken along the line Y1 after a processing operation according to one or more embodiments of the invention;

FIG. 4D depicts the cross-sectional view taken along the line Y2 after a processing operation according to one or more embodiments of the invention;

FIG. 5A depicts the cross-sectional view taken along the line X1 after a processing operation according to one or more embodiments of the invention;

FIG. 5B depicts the cross-sectional view taken along the line X2 after a processing operation according to one or more embodiments of the invention;

FIG. 5C depicts the cross-sectional view taken along the line Y1 after a processing operation according to one or more embodiments of the invention;

FIG. 5D depicts the cross-sectional view taken along the line Y2 after a processing operation according to one or more embodiments of the invention;

FIG. 6A depicts the cross-sectional view taken along the line X1 after a processing operation according to one or more embodiments of the invention;

FIG. 6B depicts the cross-sectional view taken along the line X2 after a processing operation according to one or more embodiments of the invention;

FIG. 6C depicts the cross-sectional view taken along the line Y1 after a processing operation according to one or more embodiments of the invention;

FIG. 6D depicts the cross-sectional view taken along the line Y2 after a processing operation according to one or more embodiments of the invention;

FIG. 7A depicts the cross-sectional view taken along the line X1 after a processing operation according to one or more embodiments of the invention;

FIG. 7B depicts the cross-sectional view taken along the line X2 after a processing operation according to one or more embodiments of the invention;

FIG. 7C depicts the cross-sectional view taken along the line Y1 after a processing operation according to one or more embodiments of the invention;

FIG. 7D depicts the cross-sectional view taken along the line Y2 after a processing operation according to one or more embodiments of the invention; and

FIG. 8 depicts a flow diagram illustrating a method according to one or more embodiments of the invention.

The diagrams depicted herein are illustrative. There can be many variations to the diagram or the operations described therein without departing from the spirit of the invention. For instance, the actions can be performed in a differing order or actions can be added, deleted or modified.

In the accompanying figures and following detailed description of the described embodiments of the invention, the various elements illustrated in the figures are provided with two or three-digit reference numbers. With minor exceptions, the leftmost digit(s) of each reference number correspond to the figure in which its element is first illustrated.

### DETAILED DESCRIPTION

It is understood in advance that although example embodiments of the invention are described in connection with a particular transistor architecture, embodiments of the invention are not limited to the particular transistor architectures or materials described in this specification. Rather, embodiments of the present invention are capable of being implemented in conjunction with any other type of transistor architecture or materials now known or later developed.

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

Turning now to an overview of technologies that are more specifically relevant to aspects of the present invention, ICs are fabricated in a series of stages, including a front-end-of-line (FEOL) stage, a middle-of-line (MOL) stage, and a back-end-of-line (BEOL) stage. The process flows for fabricating modern ICs are often identified based on whether the process flows fall in the FEOL stage, the MOL stage, or the BEOL stage. Generally, the FEOL stage is where device elements (e.g., transistors, capacitors, resistors, etc.) are patterned in the semiconductor substrate/wafer. The FEOL stage processes include wafer preparation, isolation, gate patterning, and the formation of wells, source/drain (S/D) regions, extension junctions, silicide regions, and liners. The MOL stage typically includes process flows for forming the contacts (e.g., CA) and other structures that communicatively couple to active regions (e.g., gate, source, and drain) of the device element. For example, the silicidation of source/drain regions, as well as the deposition of metal contacts, can occur during the MOL stage to connect the elements patterned during the FEOL stage. Layers of interconnections (e.g., metallization layers) are formed above these logical and functional layers during the BEOL stage to complete the IC. Most ICs need more than one layer of wires to form all the necessary connections, and as many as 5-12 layers are added in the BEOL process. The various BEOL layers are interconnected by vias that couple from one layer to another. Insulating dielectric materials are used throughout the layers of an IC to perform a variety of functions, including stabilizing the IC structure and providing electrical isolation of the IC elements. For example, the metal interconnecting wires in the BEOL region of the IC are isolated by dielectric layers to prevent the wires from creating a short circuit with other metal layers.

As discussed previously, a key component of the BEOL structure is the power delivery network (PDN). Backside power delivery (also referred to as a backside power delivery network) is a chip architecture that involves repositioning layers of the PDN from the top of the FEOL to the opposite side of the chip. In other words, in a backside-style architecture the PDN layers are placed on the backside of the semiconductor substrate onto which the active devices have been built. Challenges remain, however, in modifying chip architectures for backside power delivery.

One such challenge is the difficulty in co-integrating the power supply (VDD) and ground (VSS) lines (wires) and terminals of the chip with clock signals (sometimes referred to simply as “clock”) and data signals (sometimes referred to simply as “signals”). For example, if both VDD/VSS and clock signals are put on the backside of a wafer, the VDD/VSS lines should have a high capacitance to minimize decoupling capacitance while the clock signal lines should have a low capacitance to minimize clock skew and signal delay. These conflicting capacitance requirements are not compatible with typical backside-style architectures, as both VDD/VSS and clock signals are built in the same backside layer and, consequently, share a common dielectric. Compromises are required in selecting materials for the common dielectric, as the VDD/VSS lines are preferably surrounded with high-k dielectrics, while the clock signal lines are preferably surrounded with low-k dielectrics.

Turning now to an overview of aspects of the present invention, one or more embodiments of the invention address the above-described shortcomings by providing fabrication methods and resulting structures for a hybrid backside dielectric for clock and power wires. As used herein, a “hybrid” backside dielectric refers to a structural feature of one or more embodiments of this disclosure where a backside PDN (BS-PDN) is modified such that a first fraction of the interconnect lines in a given metal level on the backside of the chip are surrounded by a first dielectric material while a second fraction of the interconnect lines in the same metal level are surrounded by a second dielectric material. Notably, the first dielectric material and the second dielectric material exist in the same metal level, rather than in stacked or otherwise adjacent levels. In other words, different dielectrics are provided for different lines in the same layer (e.g., a first line or via in a metallization layer is surrounded or otherwise embedded in a first dielectric materiel while a second line or via in the metallization layer is surrounded or otherwise embedded in a second dielectric material).

In some embodiments, the first fraction of the interconnect lines is connected directly to the device region on the chip (e.g., VDD/VSS wires), while the second fraction of interconnect lines does not make connections to the device region of every cell (e.g., signal/clock wires). In some embodiments, the second fraction of interconnect lines is less than the first fraction.

Advantageously, configuring a hybrid backside dielectric in accordance with one or more embodiments increases VDD/VSS decoupling capacitance, reducing power supply noise, while also maintaining a low clock (or data) capacitance, reducing clock skew and/or signal delay. For VDD/VSS lines, replacing k=2.7 dielectrics with high-k dielectrics (e.g., dielectrics with k=5.5 or more) increases decoupling capacitance between power/ground by 1.5x to 5x. Moreover, decoupling capacitance density of up to ˜5 nF/mm is possible for multiple backside levels of VDD/VSS. For backside clock and signal, reducing k from 5.5 to 2.7 can reduce capacitance up to ˜5x.

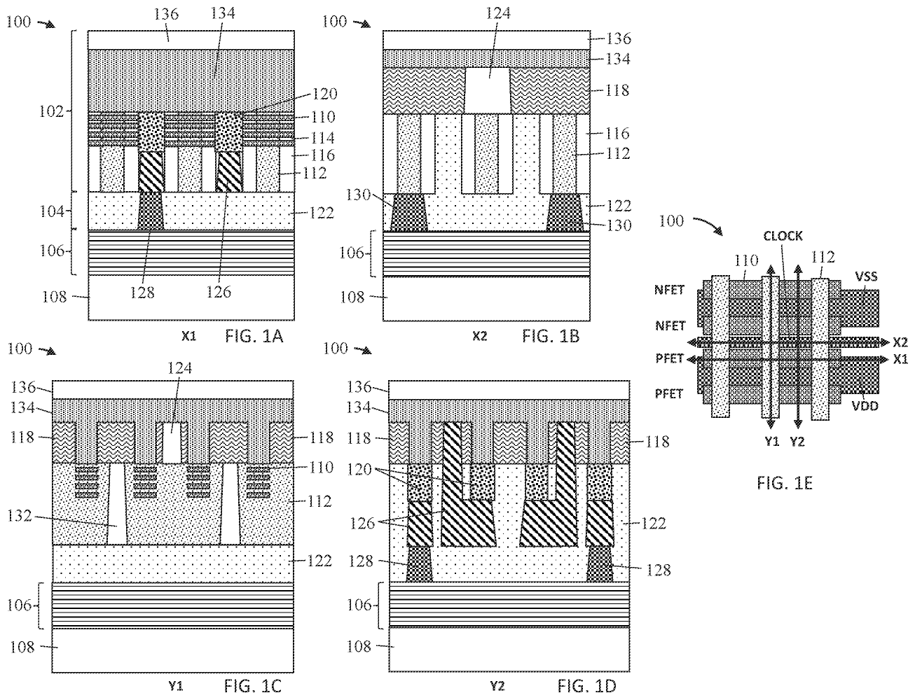

Turning now to a more detailed description of fabrication operations and resulting structures according to aspects of the invention, FIG. 1A depicts a cross-sectional view taken along the line X1 (across gate in channel region) in FIG. 1E of a semiconductor wafer 100 after an initial set of fabrication operations have been applied as part of a method of fabricating a final semiconductor device according to one or more embodiments of the invention. FIG. 1B depicts a cross-sectional view taken along the line X2 (across gate in clock/signal region) in FIG. 1E. FIG. 1C depicts a cross-sectional view taken along the line Y1 (along gate in channel region) in FIG. 1E. FIG. 1D depicts a cross-sectional view taken along the line Y2 (across source/drain regions) in FIG. 1E. FIG. 1E depicts a top-down view of the semiconductor wafer 100.

As shown in FIGS. 1A-1E, various FEOL 102, MOL 104, and BEOL 106 structures have been built in the semiconductor wafer 100, as well as a carrier wafer 108 (i.e., FIGS. 1A-1E depict the semiconductor wafer 100 post-wafer flip). The specific examples of the FEOL 102, MOL 104, and BEOL 106 are provided for ease of discussion only and are not meant to be particularly limited. For example, the FEOL 102 illustrates a nanosheet-style transistor architecture. It should be understood, however, that the nanosheet-style transistor architecture of the FEOL 102 is provided for ease of discussion only and that other transistor architectures (e.g., vertical tunneling transistors, planar transistors, finFETs, etc.) are included in the contemplated scope of this disclosure. In some embodiments, the carrier wafer 108 is formed on the BEOL 106 prior to flipping the semiconductor wafer 100.

In some embodiments, the semiconductor wafer 100 includes one or more nanosheets 110 (collectively, a nanosheet stack) and a gate 112 formed over channel regions of the one or more nanosheets 110. As used herein, a “channel region” refers to the portion of a nanosheet of the one or more nanosheets 110 over which the gate 112 is formed, and through which current passes from source to drain in the final device. The semiconductor wafer 100 can further include inner spacers 114, gate spacers 116, a shallow trench isolation (STI) region 118, source/drain (S/D) regions 120, interlayer dielectrics 122, sacrificial materials 124, contacts (e.g., S/D contacts 126), vias (S/D contact vias 128 and gate contact vias 130), and a gate cut 132, configured and arranged as shown. In some embodiments, the semiconductor wafer 100 includes a substrate 134 having a buried oxide layer 136 (i.e., an etch stop layer), although other substrate configurations are within the contemplated scope of this disclosure. In some embodiments, the substrate 134 includes a silicon-on-insulator (SOI) structure having a bottommost substrate layer (not separately shown). The bottommost substrate layer can be removed post-wafer flip, prior to the process operations shown in FIGS. 1A-1E, to expose the buried oxide layer 136.

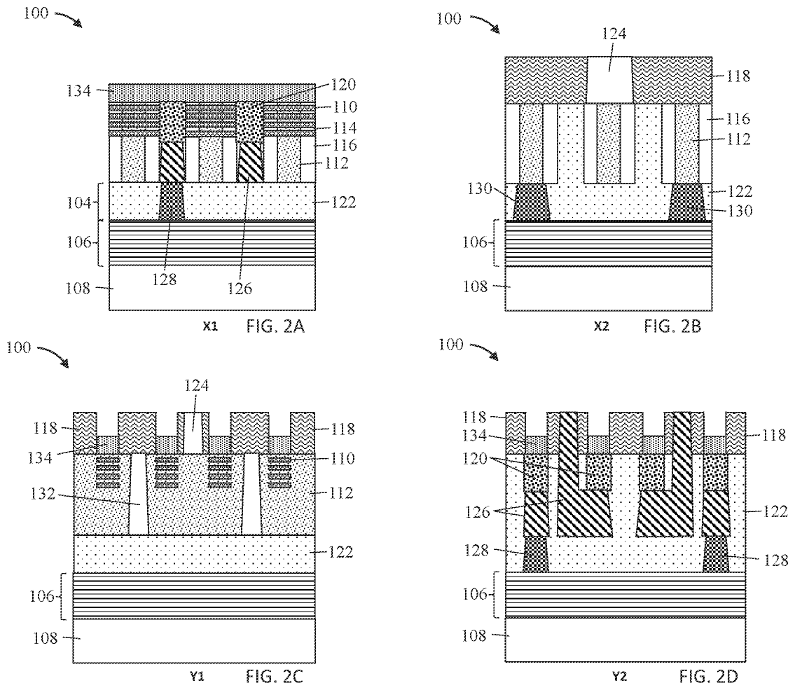

FIGS. 2A, 2B, 2C, and 2D depict cross-sectional views of the semiconductor wafer 100 taken along the lines X1, X2, Y1, and Y2, respectively, after a processing operation according to one or more embodiments. In some embodiments, the buried oxide layer 136 is removed and the substrate 134 is recessed to expose a top surface of the STI region 118 (FIGS. 2B, 2C, 2D), the sacrificial materials 124 (FIGS. 2B, 2C), and the S/D contacts 126 (FIG. 2D).

The buried oxide layer 136 can be removed and the substrate 134 can be recessed using any suitable technique, such as, for example, using a wet etch, a dry etch, or a combination of sequential wet and/or dry etches. In some embodiments, the substrate 134 can be recessed below the top surface of the STI region 118, the sacrificial materials 124, and/or the S/D contacts 126.

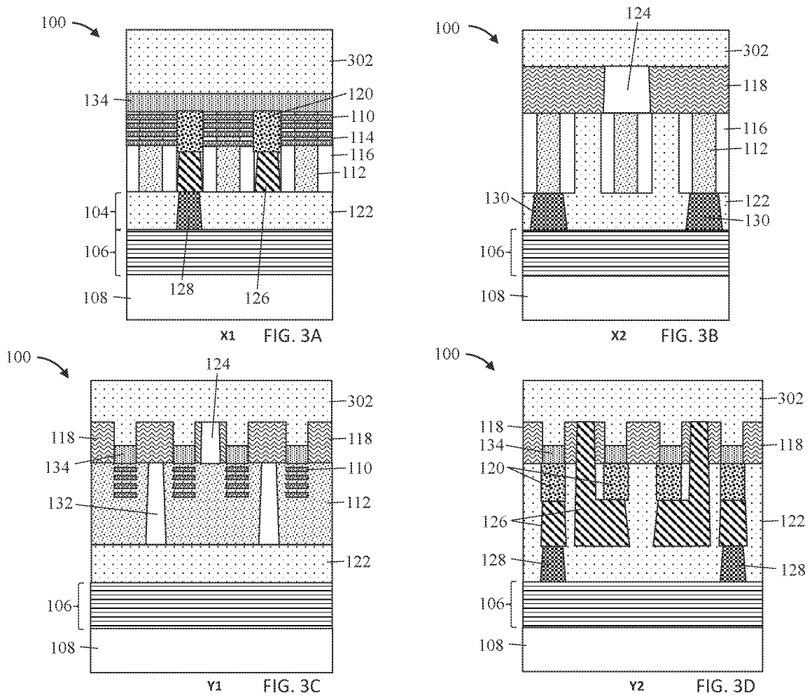

FIGS. 3A, 3B, 3C, and 3D depict cross-sectional views of the semiconductor wafer 100 taken along the lines X1, X2, Y1, and Y2, respectively, after a processing operation according to one or more embodiments. In some embodiments, a backside dielectric 302 is formed on the semiconductor wafer 100. In some embodiments, the backside dielectric 302 is deposited or otherwise formed on the recessed surface of the substrate 134 (FIGS. 3C, 3D).

In some embodiments, the backside dielectric 302 is a high-k dielectric. As used herein, a “high-k” dielectric refers to a material having a dielectric constant greater than 3.7 (i.e., a higher dielectric constant than the reference silicon dioxide, which has a dielectric constant of about 3.7 to 3.9). Examples of high-k materials include, but are not limited to, metal oxides such as hafnium oxide, hafnium silicon oxide, hafnium silicon oxynitride, lanthanum oxide, lanthanum aluminum oxide, zirconium oxide, zirconium silicon oxide, zirconium silicon oxynitride, tantalum oxide, titanium oxide, barium strontium titanium oxide, barium titanium oxide, strontium titanium oxide, yttrium oxide, aluminum oxide, lead scandium tantalum oxide, and lead zinc niobate. The high-k materials can further include dopants such as lanthanum and aluminum.

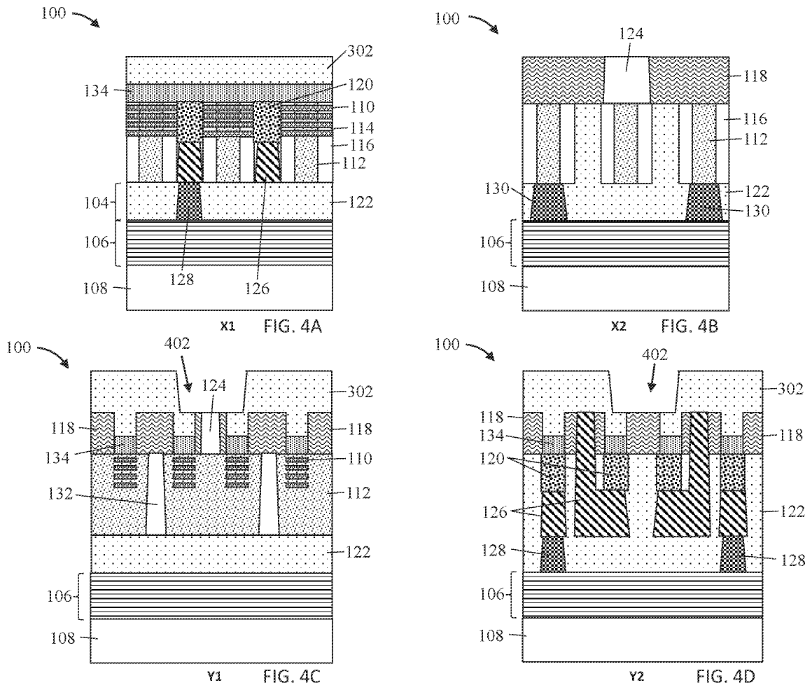

FIGS. 4A, 4B, 4C, and 4D depict cross-sectional views of the semiconductor wafer 100 taken along the lines X1, X2, Y1, and Y2, respectively, after a processing operation according to one or more embodiments. In some embodiments, portions of the backside dielectric 302 are removed to define a trench 402 (e.g., a clock signal wire opening) exposing the top surface of the sacrificial materials 124 (FIGS. 4B, 4C). The portions of the backside dielectric 302 can be removed using any suitable technique, such as, for example, using a wet etch, a dry etch, or a combination of sequential wet and/or dry etches.

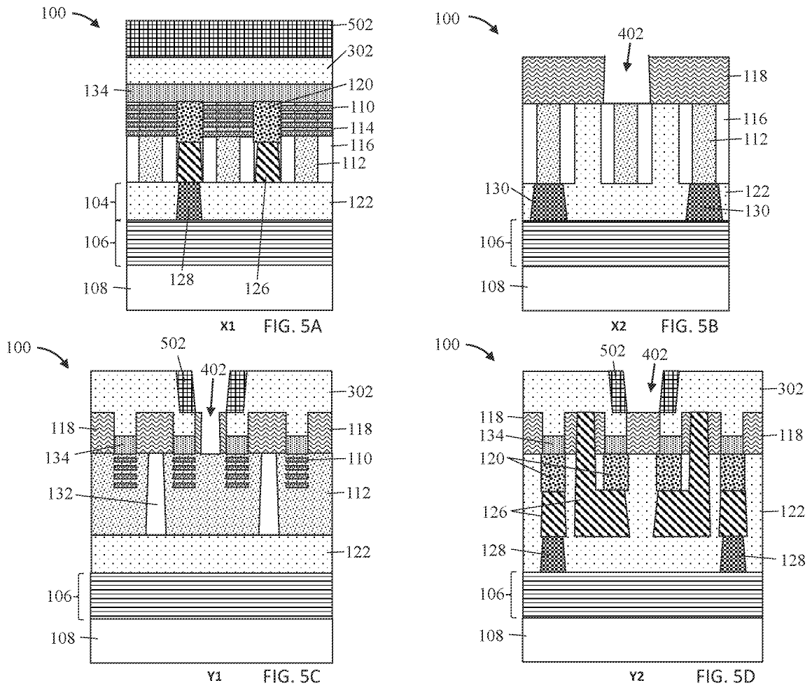

FIGS. 5A, 5B, 5C, and 5D depict cross-sectional views of the semiconductor wafer 100 taken along the lines X1, X2, Y1, and Y2, respectively, after a processing operation according to one or more embodiments. In some embodiments, a dielectric spacer 502 is deposited or otherwise formed over the backside dielectric 302 on sidewalls of the trench 402 (FIGS. 5C, 5D).

In some embodiments, the dielectric spacer 502 is a low-k dielectric. As used herein, a “low-k” dielectric refers to a material having a dielectric constant lower than 3.7 (i.e., a lower dielectric constant than the reference silicon dioxide, which has a dielectric constant of about 3.7 to 3.9). Examples of low-k materials include, but are not limited to, porous silicon dioxide, doped silicon dioxide (using, e.g., carbon, fluorine, etc.), silsesquioxanes, organosilicates, air (e.g., air gaps), etc.

As further shown in FIGS. 5B and 5C, the sacrificial materials 124 can be removed to extend the trench 402. In this manner, portions of the gate 112 and sidewalls of the STI region 118 can be exposed. The sacrificial materials 124 can be removed using any suitable technique, such as, for example, using a wet etch, a dry etch, or a combination of sequential wet and/or dry etches. In some embodiments, the sacrificial materials 124 can be removed selective to the STI region 118.

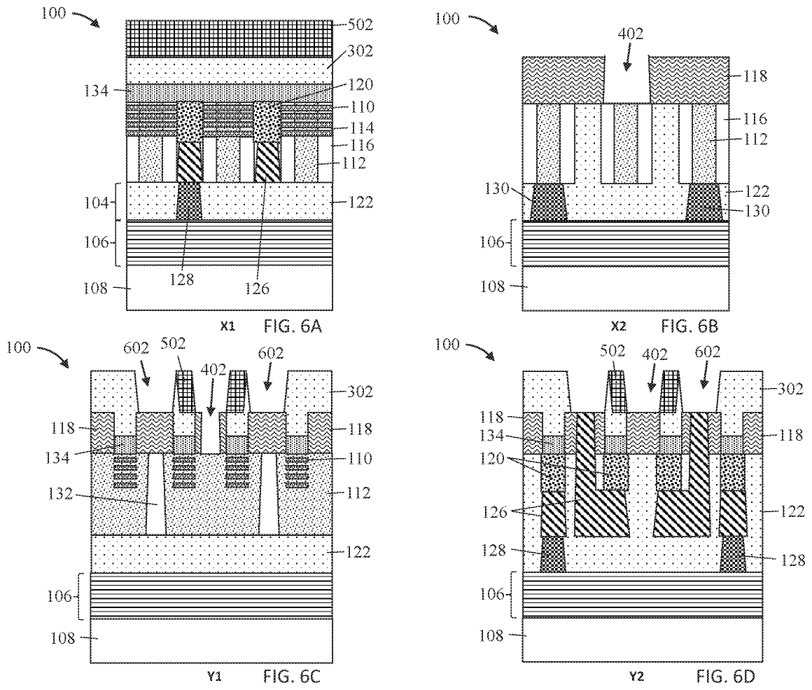

FIGS. 6A, 6B, 6C, and 6D depict cross-sectional views of the semiconductor wafer 100 taken along the lines X1, X2, Y1, and Y2, respectively, after a processing operation according to one or more embodiments. In some embodiments, portions of the backside dielectric 302 are removed to define trenches 602 (e.g., power wire openings) exposing a top surface of the S/D contacts 126 (FIG. 6D). The portions of the backside dielectric 302 can be removed using any suitable technique, such as, for example, using a wet etch, a dry etch, or a combination of sequential wet and/or dry etches.

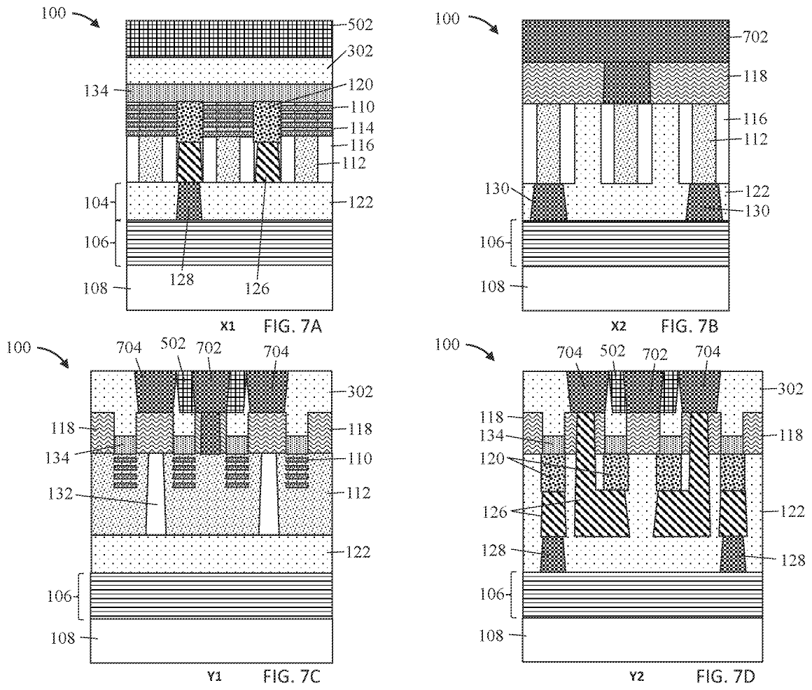

FIGS. 7A, 7B, 7C, and 7D depict cross-sectional views of the semiconductor wafer 100 taken along the lines X1, X2, Y1, and Y2, respectively, after a processing operation according to one or more embodiments. In some embodiments, the trench 402 and the trenches 602 are filled with conductive material to define a signal wire 702 and VSS/VDD power wires 704, respectively. This process can be referred to as a backside M1 metallization (i.e., a first backside metallization layer). The signal wire 702 and VSS/VDD power wires 704 can be formed from any suitable conducting material, such as, for example, metal (e.g., tungsten, titanium, tantalum, ruthenium, zirconium, cobalt, copper, aluminum, lead, platinum, tin, silver, gold), conducting metallic compound material (e.g., tantalum nitride, titanium nitride, tantalum carbide, titanium carbide, titanium aluminum carbide, tungsten silicide, tungsten nitride, ruthenium oxide, cobalt silicide, nickel silicide), conductive carbon, graphene, or any suitable combination of these materials.

After backside M1 metallization is complete, the semiconductor wafer 100 can be finalized using known processes (e.g., BEOL, far back end of line (FBEOL), packaging, etc., processes used to define a final device, including the incorporation of additional Mₓ metallization layers).

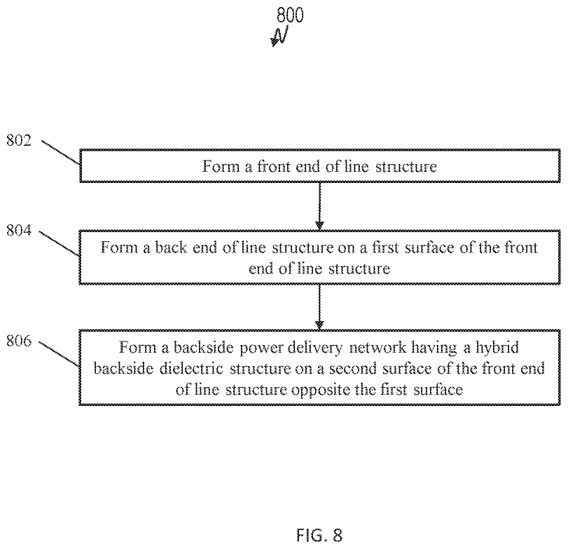

FIG. 8 depicts a flow diagram illustrating a method 800 for providing hybrid backside dielectrics for clock and power wires according to one or more embodiments of the invention. As shown at block 802, a front end of line structure is formed. At block 804, a back end of line structure is formed on a first surface of the front end of line structure.

At block 806, a backside power delivery network is formed on a second surface of the front end of line structure opposite the first surface. In some embodiments, the backside power delivery network includes a first set of interconnect lines in a first metallization level, a second set of interconnect lines in the first metallization level, and a hybrid backside dielectric structure.

In some embodiments, the hybrid backside dielectric structure includes a first dielectric material and a second dielectric material. In some embodiments, the first set of interconnect lines are embedded in the first dielectric material and the second set of interconnect lines are embedded in the second dielectric material.

In some embodiments, the first set of interconnect lines are electrically connected directly to each device region of the front end of line structure. In some embodiments, the second set of interconnect lines are not electrically connected to at least one device region of the front end of line structure.

In some embodiments, a total number of the second set of interconnect lines is less than a total number of the first set of interconnect lines.

In some embodiments, the first set of interconnect lines include power supply (VDD) and ground (VSS) terminals. In some embodiments, the second set of interconnect lines includes a clock signal wire. In some embodiments, the clock signal wire is electrically connected directly to a first gate of the front end of line structure and is electrically isolated from a second gate of the front end of line structure.

In some embodiments, the first dielectric material includes a first dielectric constant and the second dielectric material includes a second dielectric constant less than the first dielectric constant. In some embodiments, the first dielectric material includes a high-k dielectric and the first dielectric constant is greater than 3.7. In some embodiments, the second dielectric material includes a low-k dielectric and the second dielectric constant is less than 3.7.

The methods and resulting structures described herein can be used in the fabrication of IC chips. The resulting IC chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes IC chips, ranging from toys and other low-end applications to advanced computer products having a display, a keyboard or other input device, and a central processor.

Various embodiments of the present invention are described herein with reference to the related drawings. Alternative embodiments can be devised without departing from the scope of this invention. Although various connections and positional relationships (e.g., over, below, adjacent, etc.) are set forth between elements in the following description and in the drawings, persons skilled in the art will recognize that many of the positional relationships described herein are orientation-independent when the described functionality is maintained even though the orientation is changed. These connections and/or positional relationships, unless specified otherwise, can be direct or indirect, and the present invention is not intended to be limiting in this respect. Similarly, the term “coupled” and variations thereof describes having a communications path between two elements and does not imply a direct connection between the elements with no intervening elements/connections between them. All of these variations are considered a part of the specification. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiments or designs. The terms “at least one” and “one or more” are understood to include any integer number greater than or equal to one, i.e. one, two, three, four, etc. The terms “a plurality” are understood to include any integer number greater than or equal to two, i.e. two, three, four, five, etc. The term “connection” can include an indirect “connection” and a direct “connection.”

References in the specification to “one embodiment,” “an embodiment,” “an example embodiment,” etc., indicate that the embodiment described can include a particular feature, structure, or characteristic, but every embodiment may or may not include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper,” “lower,” “right,” “left,” “vertical,” “horizontal,” “top,” “bottom,” and derivatives thereof shall relate to the described structures and methods, as oriented in the drawing figures. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements.

Spatially relative terms, e.g., “beneath,” “below,” “lower,” “above,” “upper,” and the like, are used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device can be otherwise oriented (e.g., rotated 90 degrees or at other orientations), and the spatially relative descriptors used herein should be interpreted accordingly.

The terms “about,” “substantially,” “approximately,” and variations thereof, are intended to include the degree of error associated with measurement of the particular quantity based upon the equipment available at the time of filing the application. For example, “about” can include a range of ±8% or 5%, or 2% of a given value.

The phrase “selective to,” such as, for example, “a first element selective to a second element,” means that the first element can be etched and the second element can act as an etch stop (i.e., the second element remains).

The term “conformal” (e.g., a conformal layer or a conformal deposition) means that the thickness of the layer is substantially the same on all surfaces, or that the thickness variation is less than 15% of the nominal thickness of the layer.

The terms “epitaxial growth and/or deposition” and “epitaxially formed and/or grown” mean the growth of a semiconductor material (crystalline material) on a deposition surface of another semiconductor material (crystalline material), in which the semiconductor material being grown (crystalline overlayer) has substantially the same crystalline characteristics as the semiconductor material of the deposition surface (seed material). In an epitaxial deposition process, the chemical reactants provided by the source gases can be controlled and the system parameters can be set so that the depositing atoms arrive at the deposition surface of the semiconductor substrate with sufficient energy to move about on the surface such that the depositing atoms orient themselves to the crystal arrangement of the atoms of the deposition surface. An epitaxially grown semiconductor material can have substantially the same crystalline characteristics as the deposition surface on which the epitaxially grown material is formed. For example, an epitaxially grown semiconductor material deposited on a <100> orientated crystalline surface can take on a <100> orientation. In some embodiments of the invention of the invention, epitaxial growth and/or deposition processes can be selective to forming on semiconductor surface, and may or may not deposit material on other exposed surfaces, such as silicon dioxide or silicon nitride surfaces.

As used herein, “p-type” refers to the addition of impurities to an intrinsic semiconductor that creates deficiencies of valence electrons. In a silicon-containing substrate, examples of p-type dopants, i.e., impurities, include but are not limited to, boron, aluminum, gallium, and indium.

As used herein, “n-type” refers to the addition of impurities that contributes free electrons to an intrinsic semiconductor. In a silicon containing substrate examples of n-type dopants, i.e., impurities, include but are not limited to antimony, arsenic and phosphorous.

As previously noted herein, for the sake of brevity, conventional techniques related to semiconductor device and integrated circuit (IC) fabrication may or may not be described in detail herein. By way of background, however, a more general description of the semiconductor device fabrication processes that can be utilized in implementing one or more embodiments of the present invention will now be provided. Although specific fabrication operations used in implementing one or more embodiments of the present invention can be individually known, the described combination of operations and/or resulting structures of the present invention are unique. Thus, the unique combination of the operations described in connection with the fabrication of a semiconductor device according to the present invention utilize a variety of individually known physical and chemical processes performed on a semiconductor (e.g., silicon) substrate, some of which are described in the immediately following paragraphs.

In general, the various processes used to form a micro-chip that will be packaged into an IC fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), chemical-mechanical planarization (CMP), and the like. Reactive ion etching (RIE), for example, is a type of dry etching that uses chemically reactive plasma to remove a material, such as a masked pattern of semiconductor material, by exposing the material to a bombardment of ions that dislodge portions of the material from the exposed surface. The plasma is typically generated under low pressure (vacuum) by an electromagnetic field. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device. Semiconductor lithography is the formation of three-dimensional relief images or patterns on the semiconductor substrate for subsequent transfer of the pattern to the substrate. In semiconductor lithography, the patterns are formed by a light sensitive polymer called a photo-resist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

The flowchart and block diagrams in the Figures illustrate possible implementations of fabrication and/or operation methods according to various embodiments of the present invention. Various functions/operations of the method are represented in the flow diagram by blocks. In some alternative implementations, the functions noted in the blocks can occur out of the order noted in the Figures. For example, two blocks shown in succession can, in fact, be executed substantially concurrently, or the blocks can sometimes be executed in the reverse order, depending upon the functionality involved.

The descriptions of the various embodiments of the present invention have been presented for purposes of illustration, but are not intended to be exhaustive or limited to the embodiments described. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments described herein.

What is claimed is:

1. A method for forming a semiconductor device, the method comprising:
forming a front end of line structure;
forming a back end of line structure on a first surface of the front end of line structure; and
forming a backside power delivery network on a second surface of the front end of line structure opposite the first surface, the backside power delivery network comprising:
a first set of interconnect lines in a first metallization level;
a second set of interconnect lines in the first metallization level; and
a hybrid backside dielectric structure comprising a first dielectric material and a second dielectric material, wherein the first set of interconnect lines are embedded in the first dielectric material and the second set of interconnect lines are embedded in the second dielectric material.

2. The method of claim 1, wherein the first set of interconnect lines are electrically connected directly to each device region of the front end of line structure.

3. The method of claim 1, wherein the second set of interconnect lines are not electrically connected to at least one device region of the front end of line structure.

4. The method of claim 1, wherein a total number of the second set of interconnect lines is less than a total number of the first set of interconnect lines.

5. The method of claim 1, wherein the first set of interconnect lines comprise power supply (VDD) and ground (VSS) terminals.

6. The method of claim 5, wherein the second set of interconnect lines comprise a clock signal wire.

7. The method of claim 6, wherein the clock signal wire is electrically connected directly to a first gate of the front end of line structure and electrically isolated from a second gate of the front end of line structure.

8. The method of claim 1, wherein the first dielectric material comprises a first dielectric constant and the second dielectric material comprises a second dielectric constant less than the first dielectric constant.

9. The method of claim 8, wherein the first dielectric material comprises a high-k dielectric and the first dielectric constant is greater than 3.7.

10. The method of claim 8, wherein the second dielectric material comprises a low-k dielectric and the second dielectric constant is less than 3.7.

11. A semiconductor device comprising:
a front end of line structure;
a back end of line structure on a first surface of the front end of line structure; and
a backside power delivery network on a second surface of the front end of line structure opposite the first surface, the backside power delivery network comprising:
a first set of interconnect lines in a first metallization level;
a second set of interconnect lines in the first metallization level; and
a hybrid backside dielectric structure comprising a first dielectric material and a second dielectric material, wherein the first set of interconnect lines are embedded in the first dielectric material and the second set of interconnect lines are embedded in the second dielectric material.

12. The semiconductor device of claim 11, wherein the first set of interconnect lines are electrically connected directly to each device region of the front end of line structure.

13. The semiconductor device of claim 12, wherein the second set of interconnect lines are not electrically connected to at least one device region of the front end of line structure.

14. The semiconductor device of claim 11, wherein a total number of the second set of interconnect lines is less than a total number of the first set of interconnect lines.

15. The semiconductor device of claim 11, wherein the first set of interconnect lines comprise power supply (VDD) and ground (VSS) terminals.

16. The semiconductor device of claim 15, wherein the second set of interconnect lines comprise a clock signal wire.

17. The semiconductor device of claim 16, wherein the clock signal wire is electrically connected directly to a first gate of the front end of line structure and electrically isolated from a second gate of the front end of line structure.

18. The semiconductor device of claim 11, wherein the first dielectric material comprises a first dielectric constant and the second dielectric material comprises a second dielectric constant less than the first dielectric constant.

19. The semiconductor device of claim 18, wherein the first dielectric material comprises a high-k dielectric and the first dielectric constant is greater than 3.7.

20. The semiconductor device of claim 18, wherein the second dielectric material comprises a low-k dielectric and the second dielectric constant is less than 3.7.
